(19) United States
(12) Patent Application Publication
(10) Pub. No.: US 2026/0282648 A1
(43) Pub. Date: Sep. 17, 2026

(54) PEROVSKITE LIGHT-EMITTING DEVICE AND ITS MANUFACTURING METHOD

(71) Applicant: Foundation of Soongsil University-Industry Cooperation, Seoul (KR)

(72) Inventors: Min Ho Park, Seoul (KR); Jae Geun Jung, Seoul (KR); Ye Ji Lee, Seoul (KR)

(73) Assignee: Foundation of Soongsil University-Industry Cooperation, Seoul (KR)

(21) Appl. No.: 19/566,626

(22) Filed: Mar. 13, 2026

(30) Foreign Application Priority Data
Mar. 13, 2025 (KR) 10-2025-0032477
Sep. 16, 2025 (KR) 10-2025-0132888

(51) Int. Cl. H10K 50/12; H10K 71/15; H10K 85/50

(52) U.S. Cl. CPC H10K 50/12; H10K 71/15; H10K 85/50

(57) ABSTRACT

A perovskite light-emitting device includes an anode, a perovskite light-emitting layer formed on the anode, and a cathode formed on the perovskite light-emitting layer, wherein the perovskite light-emitting layer comprises perovskite particles in which a portion of A-site is doped with a Cs dopant. A method of manufacturing the perovskite light-emitting device is also provided.

### CROSS-REFERENCE TO RELATED APPLICATION

This application claims the benefit under 35 U.S.C. § 119 (a) of Korean Patent Application Nos. 10-2025-0032477, filed on Mar. 13, 2025, and 10-2025-0132888, filed on Sep. 16, 2025, the entire disclosures of which are incorporated herein by reference for all purposes.

### BACKGROUND

### 1. Field

The present disclosure relates to a perovskite light-emitting device and a method for manufacturing the same, and in particular, to a perovskite light-emitting device having improved luminous efficiency and device stability by doping metal cations into the A-site of perovskite particles within a perovskite light-emitting layer to stabilize the lattice structure, and a method for manufacturing the same.

### 2. Description of the Background

A light-emitting diode (LED) is a core element of a display, which converts an electrical signal into light to produce a visual output, and plays an important role in determining image quality and energy efficiency. Among materials recently attracting attention as next-generation display technologies, perovskite nanocrystals (PeNCs) possess excellent optoelectronic properties, including high photoluminescence quantum yield (PLQY), narrow Full Width at Half Maximum (FWHM), solution processability, and precise tunability of emission wavelengths. Owing to these properties, light-emitting diodes employing PeNCs as light-emitting layers (PeNC-based Light-Emitting Diodes, PeLEDs) are being actively researched as next-generation light-emitting devices capable of replacing or supplementing OLEDs.

To date, the device efficiency of PeLEDs has been reported to reach levels comparable to those of OLEDs; however, limitations still exist in achieving high luminous efficiency under low driving voltages. This originates from the physical and chemical structural characteristics of PeNCs. In particular, long-chain organic ligands bound to the surface exhibit insulating properties that impede charge transport, and surface defects increase non-radiative recombination, serving as major factors that degrade luminous efficiency.

To address these problems, two main approaches have been attempted in the prior art. First, a ligand exchange process is a method for improving electrical properties by substituting highly insulating long-chain organic ligands with shorter ligands favorable for charge transport. However, because perovskite nanocrystals are ionic in nature, selecting an appropriate co-solvent during the ligand exchange process is highly challenging, and the process poses a significant risk of damaging the particle surface or destabilizing the crystal structure. Second, a core-shell structure design is a method for effectively passivating surface defects by surrounding a perovskite core with a high-quality shell. Although this method has the advantage of improving long-term stability, it requires a prolonged synthesis process and precise control of reaction conditions to grow a uniform shell with few defects, thereby increasing manufacturing costs and being disadvantageous for mass production.

In addition, instability of the perovskite crystal structure is recognized as one of the fundamental causes of degradation of driving stability and luminous efficiency of PeLEDs. Perovskites have an ABX₃ structure, wherein the size and chemical stability of A-site cations directly affect the structural stability of the crystal lattice and charge recombination characteristics. In particular, commonly used organic cations such as methylammonium (MA) or formamidinium (FA) are susceptible to degradation or decomposition under thermal, electrical, and optical conditions. Such structural instability leads to degradation of luminescence characteristics and shortened lifespan of devices during operation.

Accordingly, a technique for stabilizing the perovskite lattice by adjusting the composition of A-site cations has emerged as a promising alternative. Among such techniques, a method of doping cesium (Cs), an inorganic cation, into the A-site offers the advantages of providing superior thermal and chemical stability compared to organic cations, and stabilizing the crystal structure by minimizing lattice distortion. Cs doping can also improve charge recombination efficiency and suppress non-radiative pathways arising from surface defects, consequently improving luminous efficiency and device lifespan.

Therefore, a new approach is needed that can overcome the limitations of conventional ligand exchange and core-shell structure designs, and simultaneously improve the lattice stability and luminescence properties of PeNCs.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

The present disclosure has been made to solve the above-described issues in the prior art, and an object of the present disclosure is to stabilize the lattice structure by doping a metal cation into the A-site of perovskite particles, to improve luminescence efficiency by suppressing non-radiative recombination pathways caused by surface defects, and to simultaneously improve the long-term operational stability of the device.

In one general aspect, a perovskite light-emitting device includes an anode; a perovskite light-emitting layer formed on the anode; and a cathode formed on the perovskite light-emitting layer. The perovskite light-emitting layer comprises perovskite particles in which a portion of A-site is doped with a Cs dopant.

The perovskite particles may be represented by Chemical Formula 1 below:

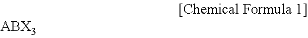

A may be an organic ammonium ion, an organic phosphonium ion, an alkali metal ion, or an amidinium-based monovalent cation. B may be any one selected from a group consisting of a transition metal, an alkaline earth metal, any metalloid, and combinations thereof. X may be at least one halogen element selected from a group consisting of Br, Cl, and I.

A may be a formamidinium ion, and B may be Pb.

A lattice of the perovskite particles may be stabilized upon doping with Cs.

The Cs dopant may be doped at a concentration of 0.001 to 2% relative to total moles of A-site cations in the perovskite particles.

The perovskite light-emitting device may further include a hole injection layer and a hole transport layer provided between the anode and the perovskite light-emitting layer.

The perovskite light-emitting device may further include an electron transport layer and an electron injection layer provided between the cathode and the perovskite light-emitting layer.

In another general aspect, a method of manufacturing a perovskite light-emitting device includes: preparing an anode; forming a perovskite light-emitting layer on the anode; and forming a cathode on the perovskite light-emitting layer. The perovskite light-emitting layer is formed to comprise perovskite particles in which a portion of A-site is doped with a Cs dopant.

The forming of the perovskite light-emitting layer may include: preparing a precursor solution by dissolving a perovskite precursor and a Cs dopant precursor in a solvent; injecting the precursor solution into an anti-solvent containing ligands to precipitate perovskite particles; purifying the precipitated perovskite particles; and spin-coating the purified perovskite particles on the anode.

The perovskite precursor may include at least one material selected from a group consisting of FABr and PbBr₂. The Cs dopant precursor may include at least one material selected from a group consisting of CsBr.

The solvent may be DMF. The anti-solvent may include toluene and butanol. The ligands may include oleic acid and oleylamine.

A combined concentration of the perovskite precursor and the Cs dopant precursor in the precursor solution may be 0.4 M.

The Cs dopant precursor may be included at 0.001 to 2% relative to total moles of the perovskite precursor.

The method may further include providing a hole injection layer and a hole transport layer between the anode and the perovskite light-emitting layer; and providing an electron transport layer and an electron injection layer between the perovskite light-emitting layer and the cathode.

The perovskite light-emitting device of the present disclosure can effectively suppress surface defects of nanocrystals and simultaneously stabilize lattice energy by adding a trace amount of dopant to commercially available perovskite nanocrystals, thereby minimizing charge traps arising from surface defects and improving charge transport due to reduced ligand density.

In addition, the perovskite light-emitting device of the present disclosure can exhibit improved luminescence efficiency, reduced driving voltage, and enhanced long-term operational stability.

In addition, the perovskite light-emitting device of the present disclosure can be driven at a lower current density while maintaining the same luminance, thereby reducing power consumption through improved external quantum efficiency.

In addition, the method of manufacturing the perovskite light-emitting device of the present disclosure involves a simple process of simultaneously introducing an A-site precursor and a dopant material into the existing commercially available perovskite nanocrystal process, thereby achieving performance improvement while maintaining existing facilities and processes, and minimizing overall manufacturing costs.

### BRIEF DESCRIPTION OF DRAWINGS

FIG. 1 is a schematic diagram showing lattice changes due to Cs doping in perovskite particles according to an embodiment of the present disclosure.

FIG. 2 is a flowchart illustrating a manufacturing process of a perovskite light-emitting device of the present disclosure.

FIG. 3 is a schematic diagram illustrating a manufacturing process of perovskite particles for forming a perovskite light-emitting layer of the present disclosure.

FIG. 4A is a photoluminescence spectrum of perovskite particles manufactured according to an embodiment of the present disclosure, showing changes according to the amount of Cs doping.

FIG. 4B is an XRD spectrum of perovskite particles manufactured according to an embodiment of the present disclosure, showing changes according to the amount of Cs doping.

FIG. 5A shows defect density as a function of Cs doping amount in perovskite particles manufactured according to an embodiment of the present disclosure.

FIG. 5B shows PLQY as a function of Cs doping amount in perovskite particles manufactured according to an embodiment of the present disclosure.

FIG. 6 is a schematic diagram showing the energy levels of a perovskite light-emitting device manufactured according to an embodiment of the present disclosure.

FIG. 7A is a schematic diagram of the structure of a perovskite hole-only device (HOD) manufactured according to an embodiment of the present disclosure.

FIG. 7B is an energy level diagram showing the energy levels of each layer constituting the HOD device of FIG. 7A.

FIG. 7C is a current density versus voltage graph showing the relationship between current density and voltage of the HOD device of FIG. 7A on a logarithmic scale.

FIG. 8A is an energy level diagram showing the energy levels of each layer of a perovskite hole-only device (HOD) manufactured according to an embodiment of the present disclosure, in units of eV.

FIG. 8B is a graph showing the relationship between capacitance and voltage of the HOD device of FIG. 8A.

FIG. 8C is a graph showing the relationship between luminance and current density of the HOD device of FIG. 8A.

FIG. 8D is a graph showing the change in external quantum efficiency (EQE) as a function of current density of the HOD device of FIG. 8A.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

A detailed description is given below, with reference to attached drawings.

### <Perovskite Light-Emitting Device>

As a means for achieving the above-described object, the present disclosure discloses a perovskite light-emitting device including perovskite particles in which a portion of A-site is doped with a Cs dopant in a perovskite light-emitting layer.

More specifically, the perovskite light-emitting device of the present disclosure may include: an anode; a perovskite light-emitting layer formed on the anode; and a cathode formed on the perovskite light-emitting layer.

Here, the anode injects holes and may have a work function of 4.8 eV or more. More specifically, the anode may be ITO, IZO, Au, or the like, but is not limited thereto.

Here, the perovskite particles included in the perovskite light-emitting layer may be represented by the following Chemical Formula 1.

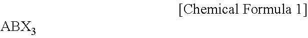

Here, A may be an organic ammonium ion, an organic phosphonium ion, an alkali metal ion, or an amidinium-based monovalent cation.

The “organic ammonium ion” may have, for example, a chemical formula of (R₁—NH₃₊) (where R₁ is a C₁-C₂₄ alkyl, a C₃-C₂₀ cycloalkyl, or a C₆-C₂₀ aryl) or a chemical formula of (R₂—C₃H₃N₂⁺—R₃) (where R₂ is a C₁-C₂₄ alkyl, a C₃-C₂₀ cycloalkyl, or a C₆-C₂₀ aryl, and R³ is hydrogen or a C₁-C₂₄ alkyl), but is not limited thereto.

The “organic phosphonium ion” may have, for example, a chemical formula of (R₄-PH3+) (where R₄ is a C₁-C₂₄ alkyl, a C₃-C₂₀ cycloalkyl, or a C₆-C₂₀ aryl), but is not limited thereto.

The “amidinium-based monovalent cation” may satisfy the following Chemical Formula 2.

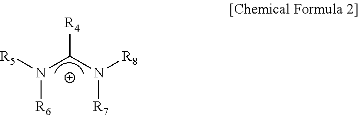

Here, R₄ to R₈ may each independently be hydrogen, a C₁-C₂₄ alkyl, a C₃-C₂₀ cycloalkyl, or a C₆-C₂₀ aryl. Specific examples may include formamidinium (NH₂CH═NH₂⁺), acetamidinium (NH₂C(CH₃)═NH₂⁺), and guanidinium (NH₂C(NH₂)═NH₂⁺), but are not limited thereto.

Here, A may most preferably be a formamidinium ion.

Here, B may be any one selected from the group consisting of a transition metal, an alkaline earth metal, any metalloid, or a combination thereof.

The “any metalloid” may be, for example, any one selected from the group consisting of lead (Pb), tin (Sn), germanium (Ge), gallium (Ga), indium (In), aluminum (AI), antimony (Sb), bismuth (Bi), and polonium (Po), but is not limited thereto.

Here, B may most preferably be Pb.

Here, X may be at least one halogen element selected from the group consisting of Br, Cl, and I, but is not limited thereto.

In the present disclosure, the perovskite light-emitting layer may include perovskite particles in which a portion of the A-site is doped with a Cs dopant, as described above.

That is, the perovskite light-emitting device of the present disclosure may include perovskite particles represented by Chemical Formula 3 below as the perovskite light-emitting layer.

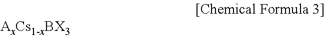

Here, A, B, and X are the same as described above, and x may be a real number of from 98 to 99.999. In other words, it is preferable that the Cs dopant is doped at a concentration of 0.001 to 2% relative to the total moles of A-site cations in the perovskite particles. When the Cs dopant is doped at less than 0.001%, a problem may occur in that the generation of halogen vacancies formed in the perovskite particles cannot be sufficiently suppressed. On the other hand, when the Cs dopant is doped at more than 2%, new defects that increase nonradiative recombination may be generated, and accordingly, a problem may occur in that luminescence is reduced. A more detailed description related to this will be given in the {Examples and Evaluation} section below.

Here, the lattice of the perovskite particles may be stabilized upon doping with Cs.

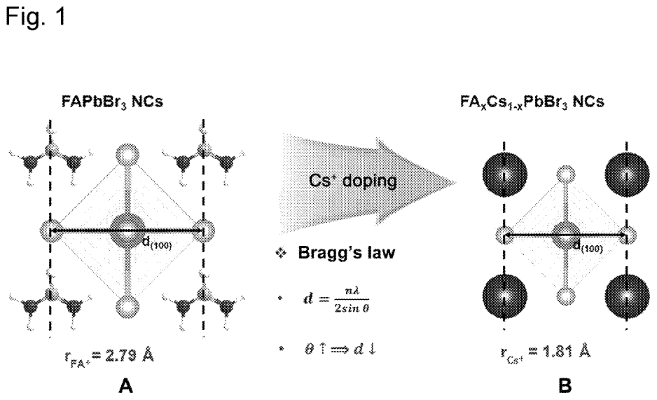

FIG. 1 is a schematic diagram showing lattice changes due to Cs doping in perovskite particles according to an embodiment of the present disclosure.

Referring to FIG. 1, it can be confirmed that the effective ionic radii of the FA ion and the Cs ion are r_{FA+}=2.79 Å and r_{Cs+}=1.81 Å, respectively. Since the effective ionic radius (r_{FA}) of the FA⁺ ion is approximately 2.79 Å, which is relatively large, the coordination angles of the PbX₆ octahedra within the crystal lattice change, and as a result, the lattice constant and inter-ionic distance increase, which may degrade the structural stability. That is, in the perovskite particles according to the present disclosure, by doping the A-site with Cs⁺, an inorganic cation having a smaller radius (r_{Cs}≈1.81 Å), instead of an organic cation, it is possible to achieve the effect of increasing the B—X—B bond angle (θ) within the octahedral coordination structure and decreasing the inter-ionic distance (d(100)). These changes improve the geometric stability of the crystal structure, and can reduce the likelihood of lattice distortion and defect formation under thermal, optical, and electrical environments. As a result, by doping Cs⁺ at the A-site, the perovskite lattice is arranged more compactly, structural stability is improved, and charge recombination efficiency within the light-emitting layer is improved, thereby significantly improving the efficiency and long-term operating characteristics of the light-emitting device.

Here, the cathode injects electrons and may have a work function of 2.5 to 4.3 eV. More specifically, the cathode may be Al, Ca/Al, Ag, LiF/Al, ZnO, TiO₂, Ba, Mg, or the like, but is not limited thereto.

Here, the perovskite light-emitting device may further include a hole injection layer and a hole transport layer provided between the anode and the perovskite light-emitting layer.

Here, the hole injection layer is a layer for adjusting energy level alignment so as to efficiently inject holes from the anode into the light-emitting layer, and may include materials such as PEDOT:PSS (Poly(3,4-ethylenedioxythiophene):poly(styrenesulfonate)), NiOx (Nickel oxide), MoO₃ (Molybdenum trioxide), V₂O₆ (Vanadium pentoxide), CuSCN (Copper (I) thiocyanate), and WOs (Tungsten trioxide), but is not limited thereto.

Here, the hole transport layer is a layer for efficiently transporting holes injected from the hole injection layer into the interior of the light-emitting layer, and may include, for example, Poly-TPD (Poly(N,N′-bis(4-butylphenyl)-N,N′-bis(phenyl)benzidine)), TFB (Poly[(9,9-dioctylfluorenyl-2,7-diyl)-co-(4,4′-(N-(4-sec-butylphenyl))diphenylamine)]), Spiro-OMeTAD (2,2′,7,7′-Tetrakis(N,N-di-p-methoxyphenyl-amine)-9,9′-spirobifluorene), CBP (4,4′-Bis(N-carbazolyl)-1,1′-biphenyl), and TPD (N,N′-Bis(3-methylphenyl)-N,N′-diphenylbenzidine), but is not limited thereto.

Here, the perovskite light-emitting device may further include an electron transport layer and an electron injection layer provided between the cathode and the perovskite light-emitting layer.

Here, the electron injection layer is a layer for easily injecting electrons from the cathode into the light-emitting layer, and may include LiF (lithium fluoride), Cs₂CO₃ (cesium carbonate), PEIE (Polyethylenimine ethoxylated), Ba (barium), Ca (calcium), or the like, but is not limited thereto.

Here, the electron transport layer is a layer for transporting electrons from the electron injection layer to the light-emitting layer and simultaneously blocking holes, and may include ZnO (zinc oxide), TiO2 (titanium dioxide), PCBM ([6,6]-Phenyl-C61-butyric acid methyl ester), TPBi (2,2′,2″-(1,3,5-Benzinetriyl)-tris(1-phenyl-1-H-benzimidazole)), BPhen (Bathophenanthroline), Alq₃ (Tris(8-hydroxyquinolinato)aluminum), or the like, but is not limited thereto.

### <Manufacturing Method of Perovskite Light-Emitting Device>

In addition, as a means for achieving the aforementioned object, the present disclosure provides a method of manufacturing a perovskite light-emitting device.

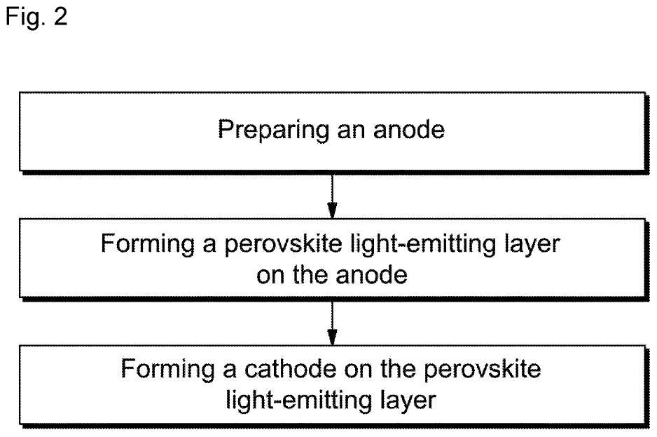

FIG. 2 is a flowchart illustrating the manufacturing process of the perovskite light-emitting device of the present disclosure.

Referring to FIG. 2, it can be confirmed that the manufacturing method of the perovskite light-emitting device of the present disclosure includes: preparing an anode; forming a perovskite light-emitting layer on the anode; and forming a cathode on the perovskite light-emitting layer.

Hereinafter, the manufacturing method of the present disclosure will be described in more detail by subdividing each step.

First, the manufacturing method of the present disclosure includes preparing an anode. The anode is an electrode in contact with the hole transport layer and serves to inject holes, and may be selected in consideration of not only electrical conductivity but also light transmittance and energy level alignment characteristics. The anode may be formed on a substrate by methods such as sputtering, thermal evaporation, and inkjet printing, and may be formed to a desired thickness (e.g., 50-200 nm), after which, if necessary, interfacial adhesion and energy alignment characteristics with the light-emitting layer may be improved through surface treatment (plasma treatment, UV-ozone treatment, etc.).

Next, the manufacturing method of the present disclosure includes forming a perovskite light-emitting layer on the anode. Here, the perovskite light-emitting layer may be formed to include perovskite particles in which a portion of the A-site is doped with a Cs dopant.

Here, forming the perovskite light-emitting layer may include preparing a precursor solution by dissolving a perovskite precursor and a Cs dopant precursor in a solvent.

Here, the perovskite precursor may include an A-site precursor represented by AX and a B-site precursor represented by BX. The composition of A, B, and X herein is as described above. More specifically, the A-site precursor is preferably FABr, and the B-site precursor is preferably PbBr₂.

The Cs dopant precursor may include at least one material selected from the group consisting of CsBr, CsI, and CsF.

Here, the solvent may be at least one selected from the group consisting of dimethylformamide (DMF), dimethyl sulfoxide (DMSO), acetonitrile, formamide, ethanolamine, isopropyl alcohol, methanol, ethanol, acetone, methyl acetate, ethyl acetate, and mixtures thereof, but is not limited thereto.

Here, the combined concentration of the perovskite precursor and the Cs dopant precursor in the precursor solution is preferably 0.4 M.

Here, the Cs dopant precursor is preferably included at 0.001 to 2% relative to the total moles of the perovskite precursor.

Next, forming the perovskite light-emitting layer may include injecting the precursor solution into an anti-solvent containing ligands to precipitate perovskite particles.

Here, the anti-solvent refers to an organic solvent with a significantly different solubility parameter from the target solvent, i.e., a liquid organic compound in which any substance, in particular a polymer substance, does not dissolve. Such an anti-solvent (non-solvent) is used as a promoter for purification, agglomeration, and precipitation of polymers. More specifically, the anti-solvent may be at least one material selected from the group consisting of n-pentane, n-hexane, cyclohexane, n-heptane, n-octane, benzene, toluene, ethyl acetate, xylene, and butanol, but is not limited thereto.

Here, the ligands may include oleic acid and oleylamine, but are not limited thereto.

Next, forming the perovskite light-emitting layer may include purifying the precipitated perovskite particles. More specifically, the purification process may be performed by redispersing the precipitated perovskite particles into hexane.

Next, forming the perovskite light-emitting layer may include spin-coating the purified perovskite particles on the anode. The thickness of the perovskite light-emitting layer upon completion of spin-coating may be about 30 nm.

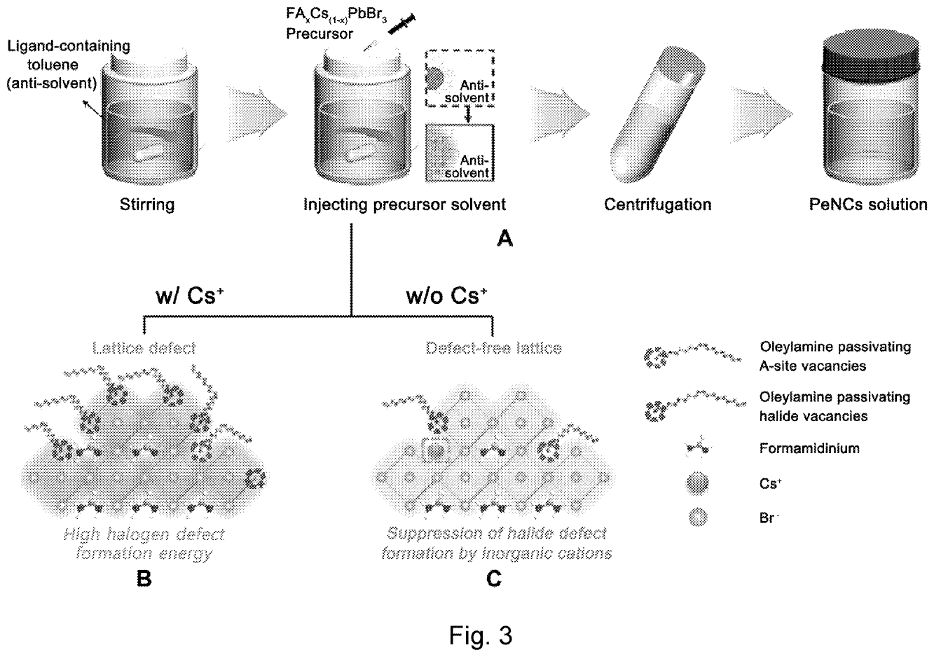

FIG. 3 is a schematic diagram illustrating the manufacturing process of perovskite particles for forming the perovskite light-emitting layer of the present disclosure.

Referring to FIG. 3, the manufacturing process of the present disclosure is described as follows. First, a perovskite precursor is prepared by mixing the precursor solutions, and a small amount of an inorganic cation (Cs) is added thereto and uniformly stirred to form a doped perovskite precursor solution. Thereafter, the nanocrystals are precipitated through a standard purification process using an anti-solvent, and then redispersed to finally obtain doped perovskite nanocrystals (FAₓCS₁₋ₓPbX₃). The process is advantageous in that it is simple and capable of mass production using a solution synthesis method.

Cs doping according to the present disclosure is achieved by substituting a portion of the formamidinium (FA) ions located at the A-site within the perovskite crystal structure with Cs ions. As shown in the lattice comparison schematic diagram below, when doping is not performed, an incomplete lattice (defective lattice) structure with numerous defects is formed, which induces high halogen defect formation energy, and ligands are abnormally bound to the surface defect sites. These defects increase nonradiative recombination pathways and act as a major cause of degraded luminescence efficiency. On the other hand, when an inorganic cation (Cs) is doped according to the present disclosure, a more compact and stabilized lattice (defect-free lattice) structure is formed, which maintains a more uniform crystal structure in a state in which halogen defect formation is suppressed. The introduction of Cs ions provides the effect of balancing the charge distribution within the crystal and relieving lattice stress, thereby preventing halogen ion loss and dramatically reducing the surface defect density. As a result, charge recombination efficiency is improved, and luminescence efficiency, device stability, and driving lifetime are significantly improved.

Next, the manufacturing method of the present disclosure includes forming a cathode on the perovskite light-emitting layer. The cathode is generally formed by thermal evaporation, and in some cases, a metal layer may be formed only on a specific area using a shadow mask. After forming the cathode, an encapsulation process may be performed on the entire device as necessary to protect the device from degradation caused by oxygen and moisture.

Here, the method may further include: providing a hole injection layer and a hole transport layer between the anode and the perovskite light-emitting layer; and providing an electron transport layer and an electron injection layer between the perovskite light-emitting layer and the cathode.

The hole injection layer, the hole transport layer, the electron transport layer, and the electron injection layer may be formed using known methods with the materials described above. For example, they may be formed by spin-coating, vacuum deposition, or solution-based coating processes such as a slot-die method and a blade coating method. After formation, the crystallinity and adhesion of the thin film may be improved through heat treatment at a temperature of 80 to 150° C.

Hereinafter, the matters claimed in the present specification will be described in more detail with reference to the accompanying drawings and examples. However, the drawings and examples presented in the present specification may be modified in various ways by a person skilled in the art and may take various forms; therefore, the description herein is not limited to the specific disclosed forms, but should be considered to include all equivalents and substitutes included within the spirit and technical scope of the present disclosure. In addition, the accompanying drawings are provided to help a person skilled in the art understand the present disclosure more accurately, and may be shown in an exaggerated or reduced form compared to the actual.

### EXAMPLES AND EVALUATION

### Examples

### Example 1

### 1. Preparation of Perovskite Particles

A precursor solution was prepared by dissolving FABr, CsBr, and PbBr₂ in 0.5 mL of DMF. The molar ratio of FABr to CsBr was set to 98:2, and the total amount of these was set to 0.2 mmol. Separately, a solution prepared by mixing 5 mL of toluene, 2 mL of 1-butanol, 0.3 mL of oleic acid, and 39.8 μL of oleylamine was vigorously stirred, after which 0.15 mL of the precursor solution was added dropwise to this solution. After stirring, the resulting solution was centrifuged at 10,000 rpm for 10 minutes. The supernatant was then discarded and the precipitate was redispersed in hexane. To remove larger particles, the hexane dispersion was centrifuged again at 3,750 rpm for 10 minutes to obtain perovskite particles (FA_{0.98}Cs_{0.02}PbBr₃).

### 2. Manufacturing of Perovskite Light-Emitting Device

A glass substrate patterned with ITO was sequentially cleaned with acetone and isopropyl alcohol in an ultrasonic bath for 15 minutes. The cleaned ITO-patterned glass substrate was treated with UV-Ozone for 20 minutes. PEDOT:pss was spin-coated to a thickness of 30 nm and annealed at 150° C. for 30 minutes. Poly-TPD was spin-coated on the PEDOT:PSS to a thickness of 15 nm and annealed at 140° C. for 15 minutes. FA_{0.98}Cs_{0.02}PbBr₃ NCs were spin-coated at 2000 rpm for 60 seconds to a thickness of 30 nm. After deposition, in a high-vacuum thermal evaporation chamber at a pressure lower than 5×10⁻⁷ Torr, an ETL (TmPyPb/PO-T2T) of 55 nm thickness, LiF of 1 nm thickness, and Al of 100 nm thickness were sequentially deposited to manufacture a perovskite light-emitting device.

### Comparative Example 1

Perovskite particles and a perovskite light-emitting device were manufactured in the same manner as in Example 1, except that the molar ratio of FABr to CsBr was set to 96:4 (hereinafter referred to as “Comparative Example 1”).

### Comparative Example 2

Perovskite particles and a perovskite light-emitting device were manufactured in the same manner as in Example 1, except that the molar ratio of FABr to CsBr was set to 94:6 (hereinafter referred to as “Comparative Example 2”).

### Comparative Example 3

Perovskite particles and a perovskite light-emitting device were manufactured in the same manner as in Example 1, except that the molar ratio of FABr to CsBr was set to 92:8 (hereinafter referred to as “Comparative Example 3”).

### Comparative Example 4

Perovskite particles and a perovskite light-emitting device were manufactured in the same manner as in Example 1, except that the molar ratio of FABr to CsBr was set to 90:10 (hereinafter referred to as “Comparative Example 4”).

### Comparative Example 5

A perovskite particle and a perovskite light-emitting device were manufactured in the same manner as in Example 1, except that CsBr was not added and FABr was set to 100 (hereinafter referred to as “Comparative Example 5”).

### <Evaluation>

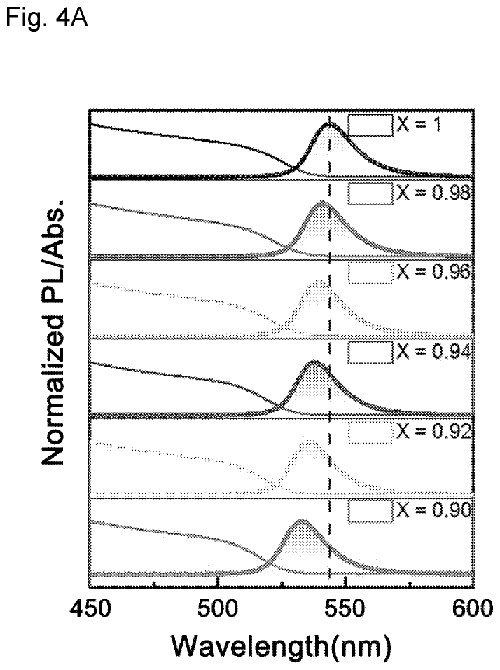

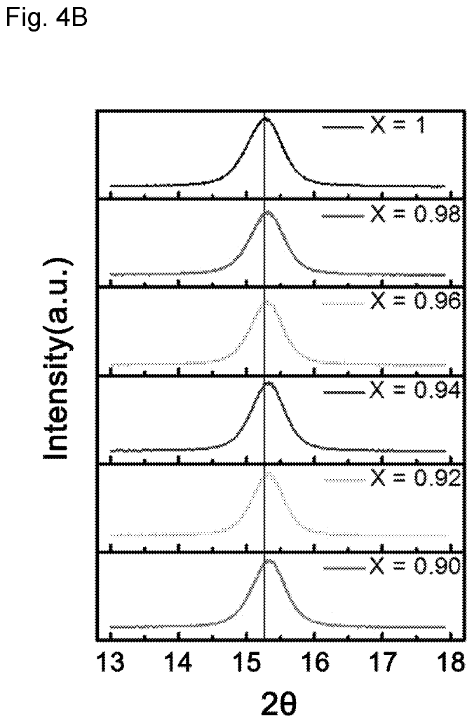

FIG. 4 shows photoluminescence spectrum and XRD spectrum according to the amount of Cs doping in perovskite particles manufactured according to an embodiment of the present disclosure. More specifically, FIG. 4A is the photoluminescence spectrum, and FIG. 4B is the XRD spectrum.

Referring to FIG. 4, the perovskite particles of the present disclosure exhibit a blue shift of the PL peak from 543.5 nm to 541 nm and then to 535.5 nm as the Cs⁺ doping concentration increases, with the excitonic peak undergoing a corresponding blue shift. This behavior can be attributed to the replacement of FA+ (ionic radius 2.79 Å) with Cs⁺ (ionic radius 1.81 Å), leading to lattice contraction. In addition, referring to the XRD spectrum, it can be confirmed that the (100) plane peak shifts to a slightly higher angle as the Cs⁺ doping concentration increases. According to Bragg's law, this change indicates a decrease in lattice spacing, which further supports the lattice contraction of perovskite due to Cs⁺ ion doping.

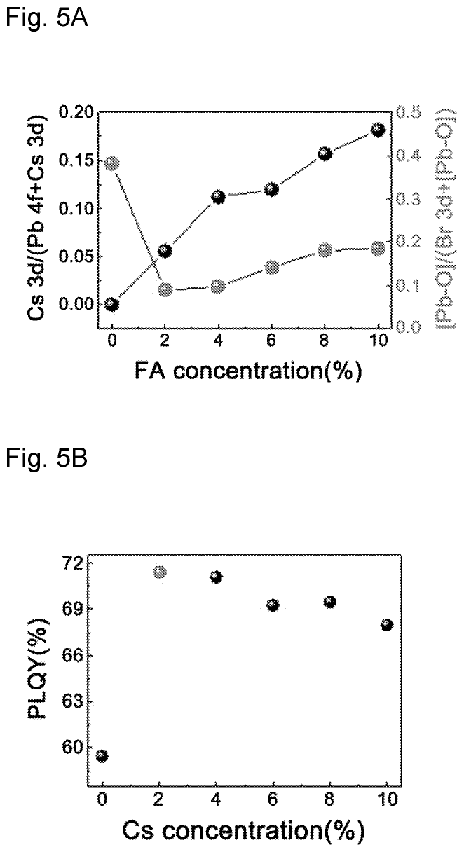

FIG. 5 shows defect density and PLQY as a function of Cs doping amount in perovskite particles manufactured according to an embodiment of the present disclosure. More specifically, FIG. 5A shows the defect density, and FIG. 5B shows the PLQY.

Referring to FIG. 5, in the case of FAPbBr₃ particles (Comparative Example 5), the atomic concentration of Cs 3d was not detected, and a sequential increase in the (Cs 3d)/(Cs 3d+Pb 4f) ratio was observed with increasing Cs⁺ doping concentration, confirming that Cs⁺ effectively substituted for FA⁺ at the A-site. In addition, to estimate the density of surface-bound oleic acid due to bromide vacancies, the oxygen atomic concentration was deconvoluted into the In—O and Pb—O bond contributions. As a result, a significant decrease in the [Pb—O]/([Pb—O]+Br 3d) ratio was observed at a 2% Cs⁺ doping concentration, which suggests the formation of the lowest density of surface bromide defects passivated by the corresponding lowest density of oleic acid. The photoluminescence quantum yield (PLQY) was highest at a 2% Cs⁺ doping concentration, which means that nonradiative recombination pathways were reduced due to passivation of surface bromide defects. FAPbBr₃ (Comparative Example 5) showed a PLQY of 59.472%, which increased to 71.259% at 2% Cs⁺ doping (Example), while Comparative Examples 1, 2, 3, and 4 showed slightly decreased PLQY values of 71.097%, 69.252%, 69.479%, and 67.978%, respectively. These results suggest that optimal passivation of bromide defects occurs at 2% doping, while excessive Cs⁺ doping forms new defects that increase nonradiative recombination.

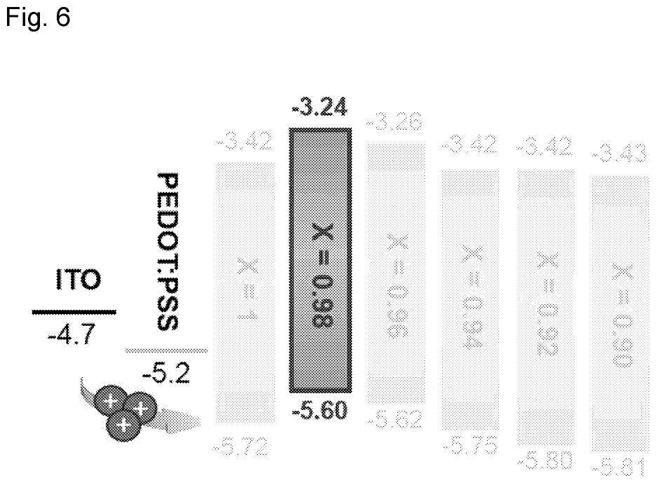

FIG. 6 is a schematic diagram showing the energy levels of a perovskite light-emitting device manufactured according to an embodiment of the present disclosure.

Referring to FIG. 6, when the doping amount is 0%, the VBM of the FA-based perovskite is located near −5.72 eV and the CBM near −3.42 eV. However, as a small amount of Cs⁺ is doped, the energy band structure changes, and in particular, when the doping ratio is about 2% (X=0.98), the CBM and VBM are adjusted to −3.24 eV and −5.60 eV, respectively, minimizing the energy level difference with PEDOT:PSS (−5.2 eV). This significantly lowers the hole injection barrier, contributing to improved charge injection efficiency and reduced operating voltage. In addition, when the Cs doping amount increases to 4% or more (X=0.96 or less), both the CBM and VBM gradually shift toward deeper levels, showing a tendency for the hole injection energy barrier with PEDOT:PSS to increase again. Therefore, the Cs doping amount has an important effect on the charge injection characteristics and energy band alignment of the light-emitting layer, and by setting the optimal doping ratio, the luminescence efficiency and operating characteristics of the device can be simultaneously improved. As a result, in the present disclosure, by adjusting the energy level of the light-emitting layer through A-site Cs doping, the hole injection barrier is minimized and charge recombination efficiency is improved, thereby lowering the operating voltage of the light-emitting device and maximizing efficiency.

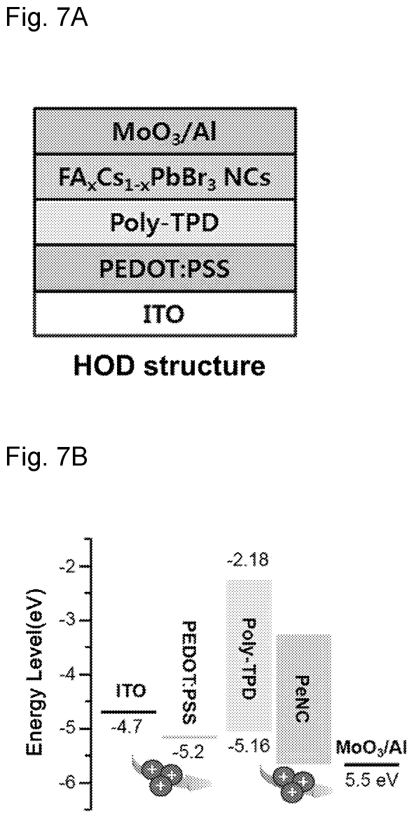

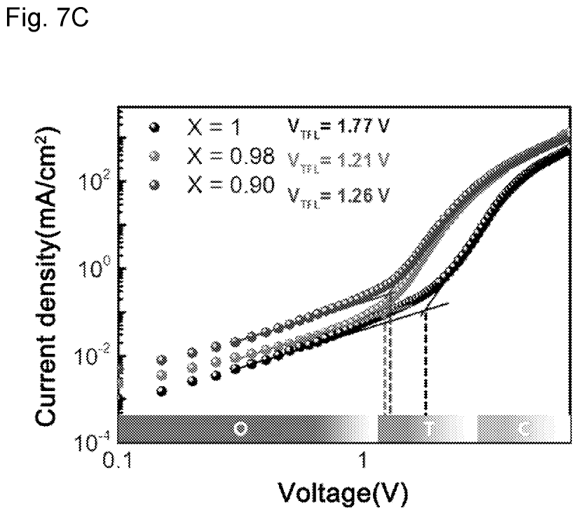

FIG. 7 illustrates a structural schematic diagram, an energy level diagram, and a current density versus voltage graph of a perovskite hole-only device (HOD) manufactured according to an embodiment of the present disclosure. More specifically, FIG. 7A is a structural schematic diagram of the HOD device, FIG. 7B shows the energy levels of each layer constituting the HOD device shown in FIG. 7A, and FIG. 7C shows the relationship between current density and voltage of the HOD device shown in FIG. 7A on a logarithmic scale. In the case of FIG. 7C, the graph is divided into three regions: the Ohmic region at low voltage, where current increases proportionally to voltage; the trap-filled limit (TFL) region at intermediate voltage, where the threshold voltage (V_{TFL}) reflects the charge trap concentration inside the light-emitting layer; and the Child's law region at high voltage, where current increases proportionally to the square of voltage.

Referring to FIG. 7, the work function of ITO is approximately −4.7 eV, and the highest occupied molecular orbital (HOMO) of PEDOT:PSS is approximately −5.2 eV. The HOMO of Poly-TPD, the hole transport layer, is −5.16 eV and the lowest unoccupied molecular orbital (LUMO) is approximately −2.18 eV, which is designed to minimize the energy barrier with the light-emitting layer (FAxCs1-xPbBr3). The work function of the MoO₃/Al electrode is approximately 5.5 eV, and it serves as an electron blocker for the light-emitting layer. Through this energy level alignment, the flow of holes through ITO→PEDOT:PSS→Poly-TPD→PeNC→MoO₃/Al is facilitated, and the effect of the energy level shift of the light-emitting layer on hole injection efficiency due to changes in Cs doping amount can be precisely analyzed. When a small amount of Cs was doped (X=0.98, 0.90), V_{TFL} was found to be lower than in the undoped case (X=1), which suggests that the charge trap density in the light-emitting layer was reduced. In particular, at the X=0.98 composition, the lowest V_{TFL} was exhibited, showing that the hole injection barrier is minimized and charge transport efficiency is maximized at the optimal doping amount. These results demonstrate that Cs doping contributes to reducing the defect density of the light-emitting layer and improving the electrical characteristics.

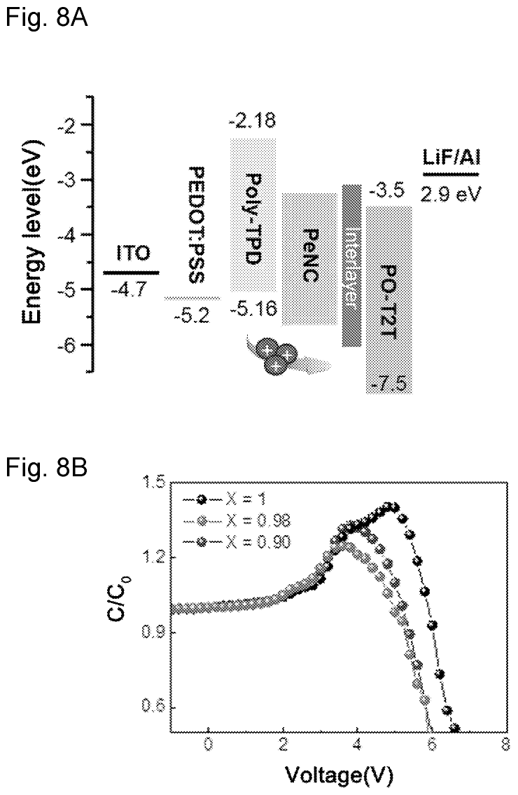

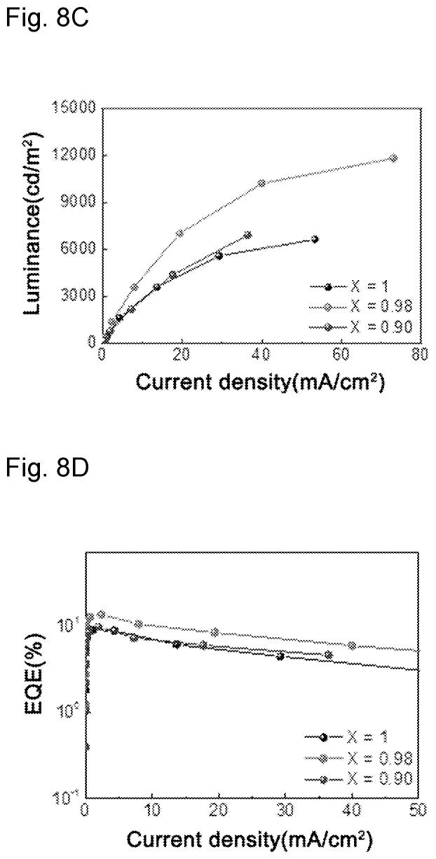

FIG. 8 illustrates a performance evaluation graph of the perovskite HOD device manufactured according to an embodiment of the present disclosure. More specifically, FIG. 8A shows the energy levels of each layer of the HOD device in units of eV, FIG. 8B is a graph showing the relationship between capacitance and voltage of the HOD device, FIG. 8C is a graph showing the relationship between luminance and current density of the HOD device, and FIG. 8D is a graph showing the change in external quantum efficiency (EQE) with current density.

First, referring to FIG. 8A, the work function of ITO is −4.7 eV, the HOMO of PEDOT:PSS is −5.2 eV, and the HOMO of Poly-TPD is −5.16 eV with a LUMO of −2.18 eV. The energy level of PeNC, the light-emitting layer, is adjusted according to the Cs doping amount, and the electron transport layer PO-T2T has a LUMO of −3.5 eV and a HOMO of −7.5 eV, forming a structure favorable for electron transport. The LiF/Al electrode has a work function of approximately 2.9 eV and serves to lower the electron injection barrier. It can be confirmed that through this energy alignment, holes and electrons from the anode and cathode are designed to effectively recombine within the light-emitting layer. Next, referring to FIG. 8B, the C/C₀ value shows a similar level near 0 V and gradually increases with increasing voltage, then sharply decreases after a specific voltage. When a small amount of Cs was doped (X=0.98), the voltage to reach maximum capacitance was the lowest, suggesting that charge accumulation and injection characteristics within the light-emitting layer were improved. This means that the hole injection barrier is lowered and charge recombination occurs efficiently. Next, referring to FIG. 8C, when the Cs doping ratio was 0.98, the luminance versus current density was the highest, showing superior luminescence performance compared to the undoped (X=1) and overdoped (X=0.90) conditions. This is interpreted as a result of maximized luminescence efficiency due to minimized defect density at the optimal doping amount. Referring to FIG. 8D, the highest EQE was maintained across all current density ranges under the Cs doping ratio X=0.98 condition, while EQE was relatively low at undoped (X=1) and overdoped (X=0.90). In particular, at X=0.98, a high initial EQE was shown in the low current density region, and the efficiency roll-off was gradual even at high current densities. This means that the balance of charge injection and recombination is optimally adjusted.

In the perovskite light-emitting device of the present disclosure, by adding a trace amount of dopant to commercially available perovskite nanocrystals, surface defects of the nanocrystals can be effectively suppressed and lattice energy can be simultaneously stabilized, thereby minimizing charge traps originating from surface defects and improving charge conductivity due to reduced ligand density.

In addition, the perovskite light-emitting device of the present disclosure can exhibit improved luminescence efficiency, reduced operating voltage, and improved device lifetime characteristics during long-term operation.

In addition, the perovskite light-emitting device of the present disclosure can be operated at a lower current density while maintaining the same luminance, and can reduce power consumption due to improved external quantum efficiency.

In addition, the manufacturing method of the perovskite light-emitting device of the present disclosure is a simple process in which an A-site precursor and a dopant material are simultaneously introduced into the existing commercially available perovskite nanocrystal process, and can achieve performance improvement while maintaining the existing equipment and process as is, thereby minimizing production costs and process costs.

The foregoing description merely illustrates the technical idea of the present disclosure by way of example, and various modifications and variations will be possible by a person skilled in the art to which the present disclosure pertains without departing from the essential characteristics of the present disclosure.

Therefore, the embodiments disclosed in the present disclosure are not intended to limit the technical idea of the present disclosure but to describe it, and the scope of the technical idea of the present disclosure is not limited by these embodiments. The scope of protection of the present disclosure should be interpreted by the following claims, and all technical ideas within an equivalent scope should be interpreted as being included in the scope of rights of the present disclosure.

What is claimed is:

1. A perovskite light-emitting device comprising:
an anode;
a perovskite light-emitting layer formed on the anode; and
a cathode formed on the perovskite light-emitting layer,
wherein the perovskite light-emitting layer comprises perovskite particles in which a portion of A-site is doped with a Cs dopant.

2. The perovskite light-emitting device of claim 1,
wherein the perovskite particles are represented by Chemical Formula 1 below: 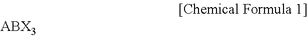
wherein A is an organic ammonium ion, an organic phosphonium ion, an alkali metal ion, or an amidinium-based monovalent cation,
B is any one selected from a group consisting of a transition metal, an alkaline earth metal, any metalloid, and combinations thereof, and
X is at least one halogen element selected from a group consisting of Br, Cl, and I.

3. The perovskite light-emitting device of claim 1,
wherein A is a formamidinium ion, and B is Pb.

4. The perovskite light-emitting device of claim 1,
wherein a lattice of the perovskite particles is stabilized upon doping with Cs.

5. The perovskite light-emitting device of claim 1,
wherein the Cs dopant is doped at a concentration of 0.001 to 2% relative to total moles of A-site cations in the perovskite particles.

6. The perovskite light-emitting device of claim 1, further comprising:
a hole injection layer and a hole transport layer provided between the anode and the perovskite light-emitting layer.

7. The perovskite light-emitting device of claim 1, further comprising:
an electron transport layer and an electron injection layer provided between the cathode and the perovskite light-emitting layer.

8. A method of manufacturing a perovskite light-emitting device, comprising:
preparing an anode;
forming a perovskite light-emitting layer on the anode; and
forming a cathode on the perovskite light-emitting layer,
wherein the perovskite light-emitting layer is formed to comprise perovskite particles in which a portion of A-site is doped with a Cs dopant.

9. The method of claim 8,
wherein the forming of the perovskite light-emitting layer comprises:
preparing a precursor solution by dissolving a perovskite precursor and a Cs dopant precursor in a solvent;
injecting the precursor solution into an anti-solvent containing ligands to precipitate perovskite particles;
purifying the precipitated perovskite particles; and
spin-coating the purified perovskite particles on the anode.

10. The method of claim 9,
wherein the perovskite precursor comprises at least one material selected from a group consisting of FABr and PbBr₂, and
the Cs dopant precursor comprises at least one material selected from a group consisting of CsBr.

11. The method of claim 9,
wherein the solvent is DMF,
the anti-solvent comprises toluene and butanol, and
the ligands comprise oleic acid and oleylamine.

12. The method of claim 9,
wherein a combined concentration of the perovskite precursor and the Cs dopant precursor in the precursor solution is 0.4 M.

13. The method of claim 9,
wherein the Cs dopant precursor is included at 0.001 to 2% relative to total moles of the perovskite precursor.

14. The method of claim 8, further comprising:
providing a hole injection layer and a hole transport layer between the anode and the perovskite light-emitting layer; and
providing an electron transport layer and an electron injection layer between the perovskite light-emitting layer and the cathode.
